(19) United States
(12) Patent Application Publication
(10) Pub. No.: US 2007/0272516 A1
(43) Pub. Date: Nov. 29, 2007

(54) Transport device

(75) Inventor: Heinz Klingl, Neusass (DE)

Correspondence Address: EDWARDS ANGELL PALMER & DODGE LLP, P.O. BOX 55874, BOSTON, MA, 02205, US

(73) Assignee: Atotech Deutschland GmbH, Berlin (DE)

(21) Appl. No.: 11/596,142

(22) PCT Filed: Apr. 13, 2005
(86) PCT No.: PCT/EP05/03895

§ 371 Date: Nov. 10, 2006

(30) Foreign Application Priority Data
May 13, 2004 (DE) 10 2004 023 909.6

(51) Int. Cl. H05K 3/00; B65G 29/00

(52) U.S. Cl. 198/463.1

(57) ABSTRACT

A conveying device according to the invention for moving stock to be conveyed (1), in the form of printed circuit boards or conductor foils to be treated, in wet-chemical or electrolytic surface treatment plants, comprises conveying means (2) which, by a rotational movement, move the stock to be conveyed (1) in a conveying direction, spindle parts (4) with a thread-like structure (8, 9) at an outer surface, and rotation means in the form of mating wheels (5) provided with cams (6), the cams (6) engaging in the thread-like structure (8, 9) of the spindle part (4) and thus imparting a uniform rotational movement to the conveying means (2). The spindle parts (4) are preferably mounted on a drive shaft (3) which is arranged parallel to the conveying direction of the stock to be conveyed (1).

The present invention relates to a conveying device, in particular a conveying device for stock to be conveyed in the form of workpieces to be treated in a wet-chemical treatment plant, for example printed circuit boards or conductor foils.

Plants for the treatment of workpieces, for example plants for the wet-chemical treatment of printed circuit boards or conductor foils, are frequently designed as so-called continuous plants, through which the workpieces to be treated are conveyed, for example in a horizontal direction, while being sprayed, jetted or wave-treated by a treatment medium. For this, suitable nozzles for emitting the treatment medium are arranged along a conveying path. Conveyance of the workpiece to be treated or stock to be treated through the plant is effected, especially in the case of flat stock to be treated, with the aid of conveying means in the form of rotating rolls, rollers or wheels. The stock to be treated can rest loosely on the conveying means or be moved by conveying means arranged on both sides of the conveying path. The arrangement of the conveying means on both sides is advantageous particularly when the treatment medium exerts a pressure against the stock to be treated. A further reason for arranging conveying means on both sides can also be for improved force transmission to the stock for treatment or stock for conveyance which is to be conveyed, so that slipping of the conveying means and thus a backup in the plant is avoided. In the case of an arrangement of the conveying means on both sides, the stock to be conveyed is effectively prevented from being deflected from the path, for example by the treatment medium. This can be effected in a horizontal continuous plant, for example, by conveying means which are arranged on an upper side of the conveying path fixing the stock to be conveyed, by means of their own weight, through additional weights or by spring pressure, in relation to conveying means arranged on a lower side of the conveying path. The stock to be conveyed is in this case moved along the conveying path in a conveying direction by the contact with the conveying means which are rotating. Generally, a plurality of similarly designed conveying means are arranged along the conveying path.

Driving of the conveying means is generally effected via a drive shaft which runs parallel to the conveying direction and the rotational movement of which is suitably linked to the rotational movement of the conveying means. It is typically necessary here for the rotational movement of the drive shaft about an axis of rotation running parallel to the conveying direction to be redirected into a rotational movement, about an axis of rotation extending perpendicular thereto, of the conveying means.

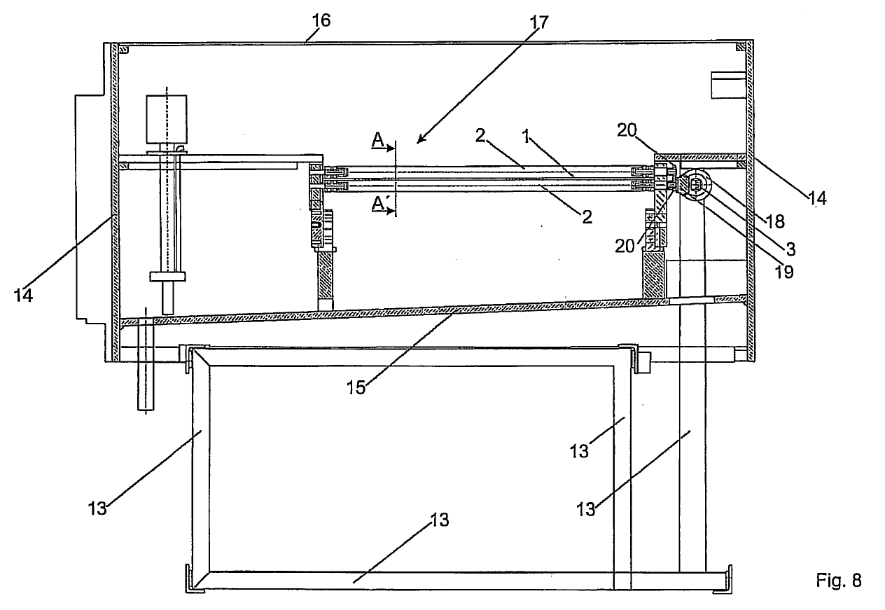

FIG. 8 shows a cross-section through a horizontal continuous plant for the wet-chemical treatment of flat stock to be treated in the form of printed circuit boards or conductor foils, the section passing through perpendicular to the conveying direction of the stock to be treated. The stock to be treated 1 moves into the plane of the drawing in this illustration. The entire plant rests on a container substructure 13. A treatment zone 17 is bounded by a bottom 15, side walls 14 and a removable cover 16 and extends in a lateral direction perpendicular to the conveying direction. Preparation facilities for the treatment medium are accommodated on one side of the treatment zone 17. Situated on the opposite side in this example is a drive system of the conveying means 2. In this example, the conveying means 2, which move the stock to be treated 1 through the plant, are designed in the form of rolls or wheels. Along the conveying direction, a plurality of the conveying means 2 are provided (not illustrated). For driving the conveying means 2, a drive shaft 3 runs in the conveying direction of the stock to be treated 1. For each of the conveying means 2 which is arranged on a lower side of the conveying path of the stock to be treated 1, a bevel wheel 18 is mounted on the drive shaft 3. This bevel wheel is in engagement with a mating bevel wheel 19 which is rigidly mounted on an axis of rotation of the conveying means 2 arranged on the lower side of the conveying path. The arrangement consisting of the bevel wheel 18 and the mating bevel wheel 19 enables the necessary redirection of the rotational movement of the drive shaft 3 into the rotational movement of the conveying means 2. Conveying means 2 arranged on the upper side of the conveying path are driven, via toothed wheels 20, by the conveying means 2 arranged on the lower side of the conveying path. The rotational movement of the drive shaft 3 is produced, for example, by means of an electric motor (not illustrated).

In order to be able to compensate for variations of the thickness of the stock to be treated 1, in a vertical direction perpendicular to the conveying direction, the upper conveying means 2 are mounted in a groove-like guide. This mounting enables a vertical movement of the upper conveying means 2, i.e. upwards and downwards. If thicker stock to be treated is conveyed through the plant, the upper conveying means 2 are raised upwards by the stock to be treated 1 which is moving through the plant. Conversely, in the case of thinner stock to be treated 1, the upper conveying means 2 move downwards, for example by virtue of their own weight.

In an arrangement of this type, a problem exists in that engagement of the toothed wheels 20, which link the rotational movement of the lower conveying means 2 to the rotational movement of the upper conveying means 2, depends on the vertical position of the upper conveying means 2. If the stock to be treated 1 varies greatly in thickness, this can lead to the engagement temporarily no longer being sufficient and thereby the drive of the upper conveying means 2 jolting, become uneven or failing completely. This, in turn, can lead to a backup of the stock to be treated 1 on the conveying path and thus ultimately to spoilage of stock to be treated 1.

A conveying device for treatment plants of the type described above is known, for example, from DE 22 56 018 or DE 30 01 726. Furthermore, from U.S. Pat. No. 4,459,183 a conveying device is known in which the upper conveying means are driven, via a crossed round belt, by the lower conveying means. A problem exists here in that abrasion occurs at the crossing point of the belt, and the abraded material can be washed along with the treatment liquid in the direction of the stock to be treated, thereby contaminating the latter.

The object of the present invention is to provide a conveying device, in particular for treatment plants of the type described above, which avoids the above-described problems of the prior art and enables in an improved manner adaptation to varying thicknesses of stock to be conveyed by the conveying device.

This object is achieved by a conveying device according to Claim 1. The dependent claims define preferred and advantageous embodiments of the invention.

According to the invention, the conveying device comprises rotatably mounted conveying means for moving stock to be conveyed, for example stock to be treated in a treatment plant in the form of printed circuit boards or conductor foils, and drive means which impart a rotational movement to the conveying means, so that the stock to be conveyed is moved by the rotational movement in the conveying direction. The conveying means, which can be designed, for example, in the form of rolls, wheels or rollers, are arranged, with respect to a conveying path of the stock to be conveyed, in such a way that they come into contact with the stock to be conveyed when the latter passes through the conveying path. For this, the axis of rotation of the conveying means extends in a lateral direction perpendicular to the conveying direction. In order to be able to adapt to variations in the thickness of the stock to be conveyed, in a vertical direction perpendicular to the conveying direction, the conveying means can be mounted in a manner movable in the vertical direction. According to the invention, at least one spindle part, which is shaped like a cylinder and has a thread-like structure on an outer surface, and at least one rotation means, with projections arranged along its periphery and extending in the direction of an axis of rotation of the rotation means, are provided, the at least one spindle part and the at least one rotation means preferably being components of the drive means. The at least one rotation means can also be designed integrally or in one piece with the conveying means. The rotation means is in particular wheel-shaped and is referred to below as a “mating wheel”. The at least one spindle part and the at least one mating wheel are arranged in such a way that at least one of the projections is in engagement with the thread-like structure of the spindle part, so that a rotational movement of the spindle part is transferred into a rotational movement of the mating wheel. The rotational movement of the mating wheel is coupled to the rotational movement of the conveying means preferably by the mating wheel and the conveying means, the rotational movements of which are coupled to one another, being mounted in a manner rotating with one another on a common axis. The at least one spindle part is preferably arranged on a drive shaft running parallel to the conveying direction, so that it rotates together with the drive shaft.

The conveying device according to the invention affords the advantage that the engagement of the projections of the mating wheel, which projections can be designed, for example, as cams, in the thread-like structure of the spindle part is largely insensitive to vertical changes in position of the conveying means. This means that, in the case of a vertically movable mounting, the at least one mating wheel can move together with the conveying means in the vertical direction without engagement between the projections of the mating wheel and the thread-like structure of the spindle part being impaired. The extent of the possible vertical displacement depends above all on the diameter of the spindle part. This can be provided with little outlay in the necessary size to provide the required displacement extent of the conveying means. A further advantage is that a plurality of conveying means arranged on both sides of the conveying path can be driven by a common spindle part. In a horizontal continuous plant, these means can be especially conveying means arranged above the conveying path and conveying means arranged below the conveying path.

In this connection, the conveying device preferably comprises conveying means which are arranged on both sides of the conveying path. In this case, the conveying means on at least one side of the conveying path are preferably mounted in a manner movable in the vertical direction. A first mating wheel, the rotational movement of which is coupled to the rotational movement of conveying means arranged on a first side of the conveying path, comprises projections, for example in the form of cams, which are arranged along its periphery and extend in the direction of its axis of rotation and of which at least one is in engagement with the thread-like structure of the at least one spindle part. A second mating wheel, the rotational movement of which is coupled to the rotational movement of conveying means arranged on a second side, opposite the first side, of the conveying path, comprises projections which are arranged likewise along its periphery and extend in the direction of its axis of rotation and of which at least one is in engagement with the thread-like structure of the at least one spindle part. There is thus provided for the conveying means, on each side of the conveying path, in each case one mating wheel 5 which is set in rotational movement via the spindle part and thereby drives the conveying means coupled to it. In this way, for example conveying means on an upper and a lower side of the conveying path can be driven by a single spindle part.

The at least one spindle part is preferably arranged on a drive shaft running parallel to the conveying direction, so that it rotates together with the drive shaft. This is accomplished in such a way that the thread-like structure on the outer surface of the spindle part ensures an advance in the conveying direction on rotation of the drive shaft. A projection or cam of the mating wheel or of one of the mating wheels, which projection or cam is in engagement with the thread-like structure of the spindle part, is thus moved in the conveying direction by the rotational movement of the spindle part. As a result, the conveying means coupled to the mating wheel are, in turn, set in a rotational movement which produces the desired movement in the conveying direction of the stock to be conveyed.

The conveying device preferably comprises a plurality of conveying means which are arranged at different positions along the conveying direction. In this case, there is provided for each of the positions a spindle part which is arranged at a corresponding position of the drive shaft. As a result, the conveying means can be arranged along the conveying path and actuated by a common drive, so that reliable conveyance of the stock to be conveyed is ensured over the entire conveying path.

When conveying means are arranged on both sides of the conveying path, i.e. when, at a given position of the conveying path, conveying means are situated vertically above the conveying path and vertically below the conveying path, an axis of rotation of the at least one spindle part is situated in the vertical direction between the axis of rotation of the conveying means on the first side of the conveying path and the axis of rotation of the conveying means on the second side of the conveying path. It is thus ensured, on the one hand, that for each side of the conveying path the corresponding mating wheels are in sufficient engagement with the spindle part. On the other hand, this arrangement ensures directly that the mating wheels arranged on opposite sides of the conveying path, i.e. the first and the second mating wheel, rotate in opposite directions, so that the conveying means coupled thereto also rotate in opposite directions. The conveying means on each side of the conveying path thereby ensure conveyance in the same direction, i.e. in the conveying direction.

It is particularly advantageous if the conveying means are movably mounted on one side of the conveying path and the axis of rotation of the at least one spindle part is arranged in a manner offset, by a proportion of a maximum displacement of the movably mounted conveying means in the vertical direction, in this direction. This means that the axis of the spindle part is on the side of the movably arranged conveying means with respect to the conveying path. As a result, the range in which the movably arranged conveying means can move vertically without the corresponding mating wheel losing engagement with the spindle part is increased on this side of the conveying path.

It is furthermore possible for the conveying device to comprise, arranged parallel to the described conveying means in each case on the same side of the conveying path, further conveying means, the conveying device being designed in this case in such a way that the rotational movement of the conveying means according to the invention imparts a rotational movement with the same direction of rotation to the further conveying means. In this way, it is possible to provide on one side of the conveying path conveying means which can be movable together in the vertical direction and the rotational movements of which can be linked together in a conventional way. Since vertical movability of the conveying means and of the further conveying means relative to one another is not necessary in this case, the rotational movements can be coupled together in a conventional way, for example by toothed-wheel means. Such toothed-wheel means can be provided, for example, by toothed wheels which are mounted on the axes of the conveying means and coupled together via an intermediate toothed wheel. The intermediate toothed wheel ensures that the conveying means and further conveying means arranged beside one another on the same side of the conveying path rotate in the same direction.

The conveying means and/or the further conveying means can be designed, for example, as roll-shaped conveying means extending in the lateral direction. Alternatively, it is, however, also possible to use wheel- or roller-like conveying means in which a contact surface with the stock to be conveyed does not extend over the entire lateral width of the conveying path. Such an arrangement can comprise, for example, conveying discs which are arranged in a manner spaced apart on a common axis. In the case where the conveying device comprises a plurality of the conveying means and/or a plurality of the further conveying means, it can be particularly advantageous for the conveying discs of conveying means and/or further conveying means arranged adjacent to one another along the conveying direction to be arranged in a manner offset in the lateral direction, so that they do not overlap in the lateral direction. As a result, improved access of treatment medium to the stock to be conveyed, for example, can be ensured. A uniform contact of the conveying means and further conveying means with the stock to be conveyed can be ensured without certain regions of the stock to be conveyed being covered to a greater degree by the conveying means.

Furthermore, it is possible in this case to design the adjacently arranged wheel- or roller-like conveying means in a manner overlapping in the conveying direction. The conveying properties in particular in the case of thin stock to be conveyed are thereby improved.

The pitch of the thread-like structure of the at least one spindle part, the extent of the at least one spindle part along its axis of rotation and the radial spacing of the projections or cams of the at least one mating wheel from the axis of rotation of the mating wheel are preferably designed in such a way that, for a given rotating speed of the at least one spindle part, a desired conveying speed of the conveying means results. When designing the spindle part or spindle parts and the mating wheel or mating wheels, care should additionally be taken to ensure that the pitch of the thread-like structure of the spindle part must not be chosen to be too high in relation to the diameter of the latter. It must always be possible for at least one projection of the mating wheel to engage in the spindle part to ensure continuous uniform rotating movement. For uniform movement it is additionally important for at least one complete thread turn to be formed. Furthermore, the extent of the spindle part in the direction of its axis of rotation should not be chosen to be too great, since otherwise there is a risk of a plurality of projections of the mating wheel which are situated at different angular positions on the mating wheel from blocking the movement of the spindle part and of the mating wheel. It is therefore preferable to select the spindle part with an extent, along its axis of rotation, which is small as compared with the radial position of the projections on the mating wheels and to provide a low pitch of the thread-like structure. If the conveying device comprises a plurality of conveying means, it is furthermore advantageous, for uniform conveyance, to design the conveying device in such a way that, for each of the conveying means, the same conveying speed results. Parameters which are available for this, apart from the design of the mating wheels and spindle parts already described, are also the diameters of the conveying means themselves.

It can furthermore be advantageous to design the diameter of the mating wheels with the projections to be smaller than the outside diameter of the conveying means. This achieves the effect that adjacent mating wheels and the projections provided thereon do not obstruct one another even if the spacing of adjacent conveying means is less than the outside diameter of the conveying means.

The outside diameter of the conveying means is to be understood here as the diameter of an area which is swept by that part of the conveying means which is furthest away from the axis of rotation of the conveying means during the rotational movement of the latter. This means that in certain cases a non-circular cross-sectional shape of the conveying means can be possible. For example, the conveying means can be provided with teeth or projections which engage in the stock to be conveyed.

The conveying device according to the invention is preferably designed for use in a treatment plant for conveying flat stock to be conveyed, in the form of printed circuit boards or conductor foils to be treated, for the purpose of the wet-chemical or electrolytic treatment of the same. Such a treatment plant preferably comprises a conveying device according to the invention.

The present invention enables improved adaptation of the conveying device to variations of the thickness of the stock to be conveyed. As a result, more reliable and more effective conveyance is ensured and backups can be avoided. The adaptation to variations of the thickness of the stock to be conveyed can be achieved especially by a movable mounting of conveying means on one side of the conveying path or on both sides of the conveying path. The invention is particularly suitable for use in horizontally conveying wet-chemical treatment plants, such as, for example, for the chemical or electrolytic treatment of printed circuit boards or conductor foils. The increased reliability of the conveying device ensures, in such plants, that backups are avoided and spoilage of material caused thereby is kept low.

The invention is explained in more detail below using preferred exemplary embodiments with reference to the attached drawings.

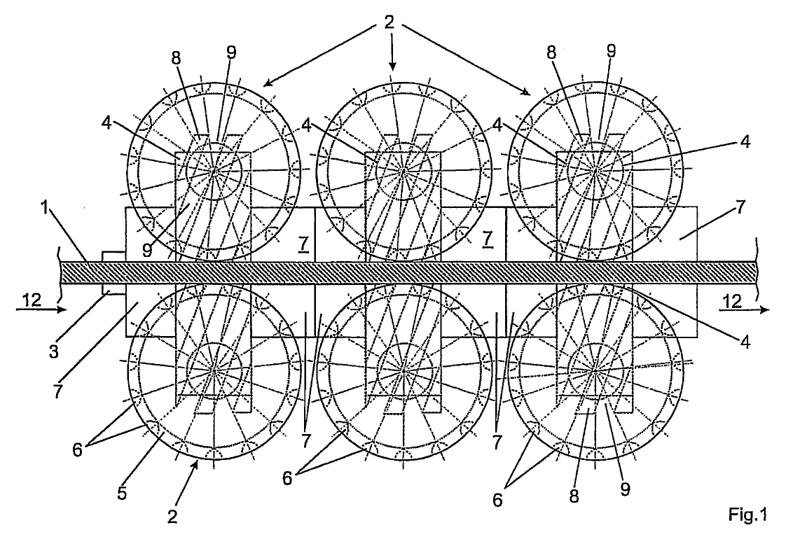

FIG. 1 shows in detail form a conveying device according to one exemplary embodiment of the invention.

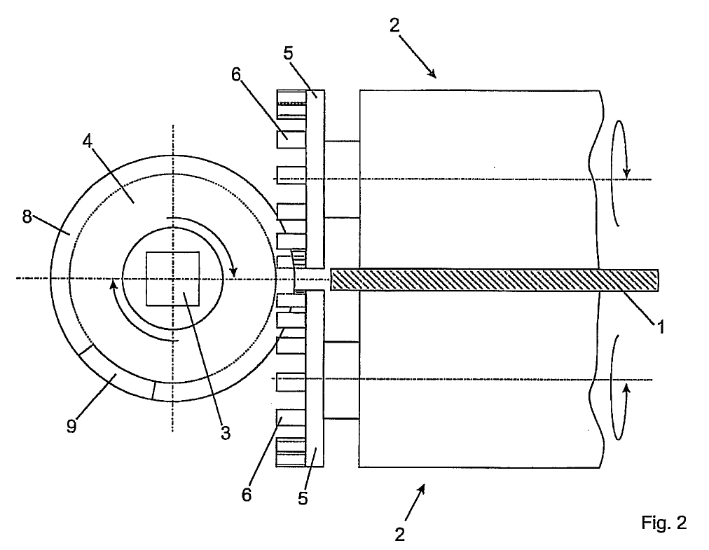

FIG. 2 shows in detail form the conveying device of FIG. 1 in a view rotated by 90°.

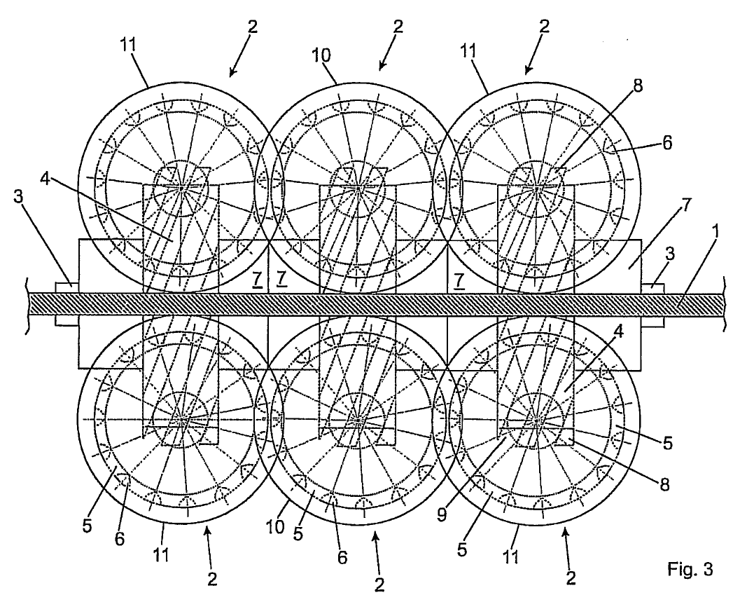

FIG. 3 shows a conveying device according to a further exemplary embodiment of the present invention.

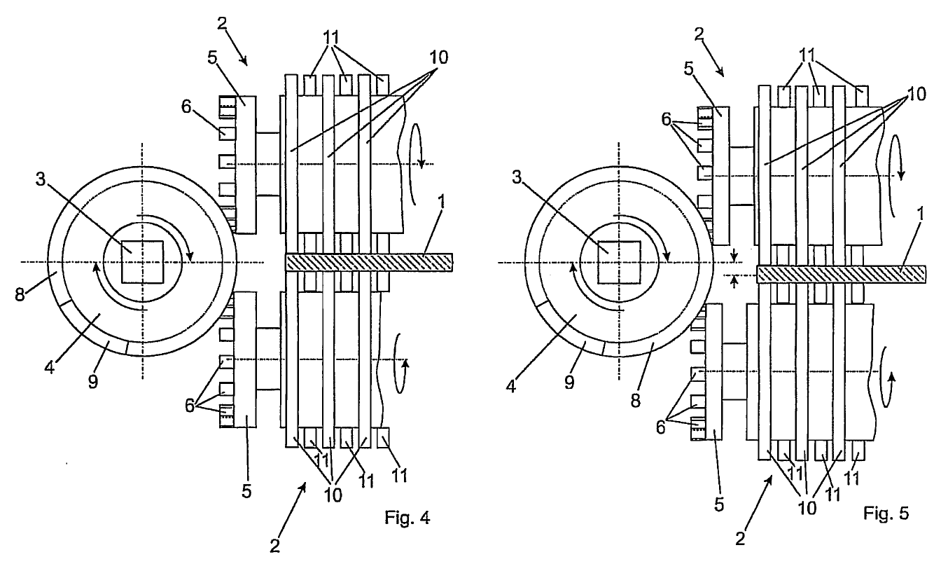

FIG. 4 illustrates in detail form the conveying device of FIG. 3 in a view rotated by 90°.

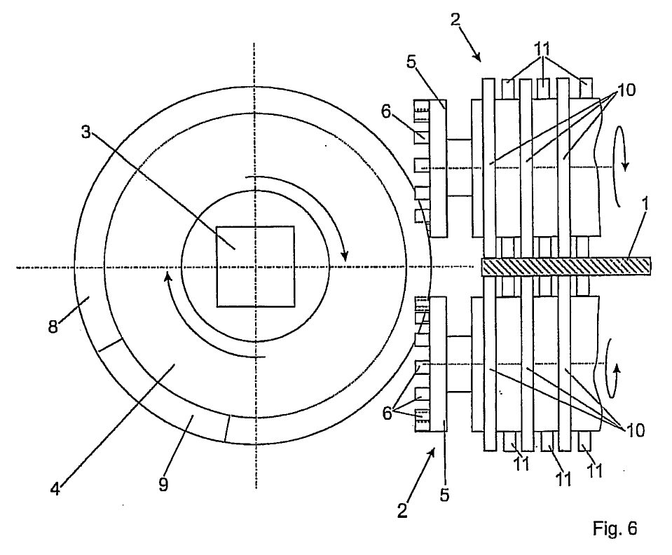

FIG. 5 shows, in the same view as FIG. 4, a conveying device according to a further exemplary embodiment of the present invention with a modified position of the axes of rotation of the conveying means.

FIG. 6 shows, in the same view as FIG. 4, a conveying device according to a further exemplary embodiment of the invention with an increased diameter of the spindle part.

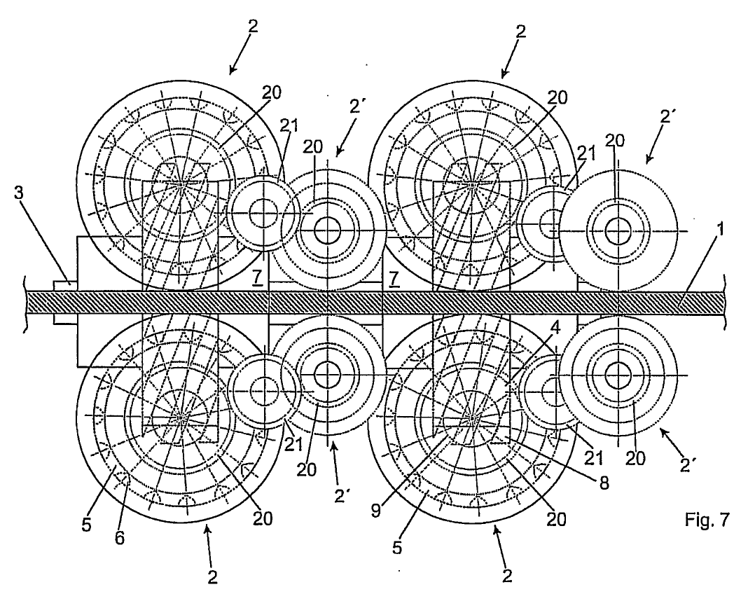

FIG. 7 shows a conveying device according to a further exemplary embodiment of the invention, which comprises further conveying means.

FIG. 8 shows a cross-sectional view of a horizontally conveying treatment plant with a conveying device according to the prior art.

FIG. 1 shows a conveying device for a treatment plant, similar to that which has been described with reference to FIG. 8 for the prior art. The illustration is in a plane parallel to a conveying direction, as indicated in FIG. 8 by the line A-A′. Only a detail of the conveying device is illustrated, i.e. from a multiplicity of conveying means 2 of the conveying device, only three are illustrated in this case.

In FIG. 1 as well as all the other figures, the mounting of the conveying means on housing walls of the treatment plant is not illustrated, for reasons of clarity. This is effected by means of bearing bores for the conveying means arranged on a lower side of the conveying path or of the stock to be conveyed and by means of an elongated-hole mounting for the conveying means arranged above the conveying path. The elongated holes extend in a vertical direction perpendicular to the conveying direction, so that the upper conveying means are mounted in a manner movable in this direction. Since the mountings in the treatment plant may come into contact with a treatment liquid or another treatment medium, they must be designed to be resistant to it. A plastic in the form of the low-pressure polyethylene RCH1000™, for example, has proved to be very suitable here for the production of the bearings.

The stock to be conveyed 1, in the form of printed circuit boards or conductor foils to be treated, passes through the plant in a conveying direction indicated by arrows 12. The drive is effected via a drive shaft 3, the axis of which runs along the treatment plant parallel to the conveying direction. At positions on the drive shaft 3 which are provided with conveying means 2, a spindle part 4 is in each case rigidly connected to the drive shaft 3. The position of the spindle parts 4 on the drive shaft 3 is fixed by spacers 7 arranged in each case between two spindle parts 4. Mating wheels 5 are in each case mounted on the axis of the conveying means 2 likewise in a manner rigidly connected to it. This means that the conveying means 2 and the mating wheels 5 rotate together. Each of the mating wheels 5 comprises, at its circular end face directed away from the conveying path of the stock to be conveyed 1, projections in the form of cams 6 which extend in the direction of the axis of rotation of the mating wheels 5, i.e. the axis of rotation of the conveying means 2. The cams 6 are arranged, at a radial position corresponding to the diameter of the roll-shaped conveying means 2, at uniform angular spacings along the periphery of the mating wheel. A pair of conveying means 2, i.e. a conveying means 2 located at a given position in the conveying direction above the conveying path and a conveying means 2 located at the corresponding position below the conveying path, is assigned in each case one of the spindle parts 4. The spindle parts 4 are substantially cylindrical and provided with a thread-like structure 8, 9 on their outer surface, i.e. the lateral surface of the cylinder. The spindle part 4 assigned to a pair of conveying means 2 is arranged in such a way opposite the mating wheels 5 mounted on the axes of the conveying means 2 that the cams 6 on the end faces of the mating wheels 5 are in engagement with the thread-like structure 8 of the spindle part 4. This means that for each of the mating wheels 5 at least one of the cams 6 is in engagement with the thread-like structure 8, 9 of the corresponding spindle part 4. The thread-like structure of the spindle parts 4 comprises helically configured projections 8 with grooves 9 lying therebetween.

A rotational movement of the drive shaft 3 and hence also of the spindle parts 4 gives rise in the thread-like structure 8, 9 to a forward movement, by which the cams in engagement with the thread-like structure 8, 9 are moved concomitantly. As a result, a rotational movement of the mating wheels 5 is produced in turn. The smaller the extent of the spindle parts 4 in the direction of their axis of rotation, i.e. in the direction of the conveying direction, the more uniform is the forward movement of the cams 6. The spindle parts 4 are, however, constructed with such a width that at least one of the cams 6 of each mating wheel 5 always engages in the thread-like structure 8, 9 of the corresponding spindle part 4, in order that the transmission of movement is not interrupted. Furthermore, the shape of the cams 6 is chosen such that the angular variation, occurring during the rotational movement of the mating wheels 5, with respect to the orientation of the thread-like structure 8, 9 does not lead to jamming of the cams 6 in the thread-like structure 8, 9. When only small forces have to be transmitted, i.e. when the drive runs smoothly, a correspondingly greater pitch of the thread-like structure 8, 9 can be chosen.

A particularly uniform rotational movement of the mating wheels 5 and hence also of the conveying means 2 can be achieved with spindle parts 4 which have a small extent in the conveying direction and at the same time a small pitch of the thread-like structure 8, 9. This is due to the fact that in this case the cams 6 move, inside the thread-like structure 8, 9, almost exclusively in the conveying direction, i.e. perpendicular to the axis of rotation of the mating wheels 5 and conveying means 2. A small pitch of the thread-like structure 8, 9 is associated with a correspondingly low speed of the rotational movement transmitted to the mating wheels 5. This can be compensated for by a correspondingly higher rotational speed of the drive shaft 3.

The thread-like structure 8, 9 of the spindle parts 4 imparts a linear movement along the conveying direction. However, the cams 6, in engagement therewith, of the mating wheels 5 execute a movement on a circular path, i.e. about the axis of rotation of the mating wheels 5 and conveying means 2. This means that engagement of the cams 6 in the thread-like structure 8, 9 of the spindle parts 4 is only possible where the circular movement of the cams 6 is compatible with the linear movement of the thread-like structure 8, 9. This is the case in a region in which the cam 6 moves substantially along the conveying direction, i.e. when the tangent to the circle described by the cam 6 at the location of the cam 6 lies substantially parallel to the conveying direction. If there are greater angular deviations between this tangent and the conveying direction, the movements become increasingly incompatible, so that the spindle parts 4 may have only a given maximum extent in the conveying direction. With increasing angular deviation between the tangent and the conveying direction, the torque transmitted to the cam 6 decreases. Furthermore, if a plurality of the cams 6 of a mating wheel 5 are simultaneously in engagement with the thread-like structure 8, 9, jamming of the cams 6 in the thread-like structure 8, 9 can occur. This is avoided by the extent of the spindle parts 4 along the conveying direction being correspondingly limited.

The cross-section of the cams 6 in a plane perpendicular to the axis of rotation of the mating wheels is shaped in such a way as to ensure as good a guidance of the cams 6 as possible without risk of jamming. For this, the cross-sectional shape can be substantially circular or composed of segments of a circle.

FIG. 2 shows a side view rotated by 900 in relation to FIG. 1. In this case, the conveying direction of the stock to be conveyed 1 extends out of the plane of the drawing. The illustration of FIG. 2 shows clearly how the cams 6 engage in the thread-like structure 8, 9 of the spindle parts 4. It can be seen that the ratio of the sizes of the mating wheels 5 and of the spindle parts 4 are chosen in such a way that only those cams 6 situated at the level of the axis of rotation of the spindle parts 4 are in engagement with the thread-like structure 8, 9 of the spindle parts 4.

It can furthermore be seen that the drive shaft 3 has a polygonal outer shape in the region of the spindle part 4. This ensures that the spindle part 4 mounted on the drive shaft 3 rotates without significant play with the drive shaft 3. Alternatively, the drive shaft 3 can have a round cross-section with key groove. The polygonal outer shape can, as illustrated, be square or else hexagonal, octagonal or toothed-wheel-shaped. The spindle part can be slipped onto the drive shaft and screwed or pressed on. A variety of other rigid mounting possibilities are, however, also conceivable.

It can furthermore be seen in FIG. 2 that, if thicker stock to be conveyed 1 is passed through the conveying path and thereby the upper conveying means 2 are displaced vertically upwards, this hardly leads to changes in respect of the engagement of the cams 6 in the thread-like structure 8, 9 of the spindle parts 4. It can also be seen that the mating wheels 5 have substantially the same diameter as the roll-shaped conveying means 2 and that the cams 6 are arranged at a radial position, corresponding to the diameter of the conveying means 2, on the outside along the periphery of the mating wheels 5. As a result, maximum engagement of the cams 6 in the thread-like structure 8, 9 of the spindle parts 4 is achieved. The axis of rotation of the spindle parts 4, i.e. the drive shaft 3, is in this case situated level with the plane of the stock to be conveyed 1 and thereby approximately centrally between the axes of rotation of the mating wheels 5 and of the conveying means 2 in the vertical direction.

FIG. 3 shows a further example of a conveying device, in which, in contrast to FIGS. 1 and 2, the conveying means 2 are not of roll-shaped, but of wheel- or roller-shaped design. This is particularly advantageous when the stock to be conveyed 1 is particularly thin. In this case, there is the risk, for example, that the stock might stick to the roll-shaped conveying means 2 described above owing to a liquid film and thereby be deflected from the conveying path.

For this reason, in the conveying device of FIG. 3, the conveying means 2 are provided with wheel- or roller-like conveying discs 10, 11. The conveying discs 10, 11 are arranged in a manner spaced apart along the axes of rotation of the conveying means 2 and offset with respect to adjacent conveying means 2. For this reason, it is possible, as illustrated in FIG. 3, for the spacing of adjacent conveying means 2 along the conveying direction to be less than the diameter of the conveying means 2. This means that, along the conveying direction, regions are formed in which adjacent conveying means 2 overlap. The remaining components of the conveying device correspond substantially to those of the conveying device of FIGS. 1 and 2. Repeated description of these elements, which are denoted by the same reference symbols, is dispensed with below.

FIG. 4 shows the conveying device of FIG. 3 in a view, corresponding to FIG. 2, horizontally rotated by 900. In contrast to the conveying device of FIG. 2, the mating wheels 5 here have a diameter which is less than the outside diameter of the conveying means 2, i.e. the outside diameter of the conveying discs 10, 11. A roll region, formed between the conveying discs 10, 11, of the conveying means 2 has a smaller diameter than the conveying discs 10, 11 and corresponds substantially to the diameter of the mating wheels 5.

As is apparent from FIGS. 3 and 4, the conveying discs 10, 11 of conveying means arranged adjacent to one another along the conveying direction are arranged offset in such a way with respect to one another that the offset-arranged conveying discs 10, 11 overlap in the conveying direction. This means that the conveying discs 11 are arranged between the conveying discs 10 in the lateral direction. For this, the spacing of the conveying discs 10, 11 on the axis of the conveying means 2 is chosen to be greater than their lateral extent, i.e. the thickness. The overlap achieves the effect that very thin stock to be conveyed 1 which is deflected from the conveying path, for example by the pressure of the treatment medium jetted or sprayed onto it, is directed back onto the conveying path again by the adjacent conveying discs 10, 11 arranged close together.

As is evident from FIG. 4, the cams 6 of the mating wheels 5 engage in the thread-like structure 8, 9 of the corresponding spindle parts 4 further away from the plane of the stock to be conveyed 1 as compared with the conveying device of FIGS. 1 and 2. This results in a reduced vertical displaceability of the upper conveying means 2 as compared with the conveying device of FIGS. 1 and 2.

A further conveying device is illustrated in FIG. 5. The conveying device of FIG. 5 corresponds substantially to the conveying device of FIGS. 3 and 4. In order to counteract the reduced vertical displaceability of the upper conveying means 2, however, the axis of rotation of the spindle parts 4 is arranged in a manner offset vertically upwards by a given amount, in contrast to the conveying devices described above. As is apparent from FIG. 5, the engagement of the mating wheels 5 of the conveying means 2 on the upper side of the conveying path or the conveying plane of the stock to be conveyed 1, i.e. on the side of the movably mounted conveying means 2, is thereby improved at the expense of the engagement of the mating wheels 5 of the conveying means 2 on the lower side of the conveying path. Since, however, the conveying means 2 on the lower side of the conveying path is not movably mounted, the engagement between the cams 6 of the mating wheels 5 and the thread-like structure 8, 9 of the spindle part 4 is not critical here. It is thus possible to achieve overall an improved tolerance to variations of the thickness of the stock to be conveyed 1, since variations in the thickness of the stock to be conveyed 1 affect only the position of the upper mating wheels 5 and for this the margin with regard to the engagement of the cams 6 with the thread-like structure 8, 9 of the spindle parts 4 has been improved.

A further possibility of increasing the vertical adjusting range in which reliable engagement of the cams 6 in the thread-like structure 8, 9 of the spindle parts 4 is ensured consists in increasing the outside diameter of the spindle parts 4. This is illustrated in FIG. 6. The conveying device illustrated in FIG. 6 otherwise corresponds to the example illustrated in FIGS. 2 and 3.

A further example of a conveying device is illustrated in FIG. 7. Like the conveying device of FIGS. 2 and 3, the conveying device of FIG. 7 comprises conveying means 2 with conveying discs. However, the conveying means 2, provided with the mating wheels 5 and driven via the spindle parts 4, are not arranged in an interlocking manner, but positioned at a given spacing from one another along the conveying direction. Arranged beside the conveying means 2, axially parallel thereto, are further conveying means 2′. In the example shown, the further conveying means 2′ have a smaller diameter than the conveying means 2. The further conveying means 2′ are likewise provided with conveying discs and the spacings and diameters of the conveying means 2 and further conveying means 2′ are designed in such way that an overlapping arrangement of the conveying discs of adjacent conveying means 2 and further conveying means 2′ is again achieved, in a way similar to that illustrated in FIG. 3.

The conveying device is designed in such a way that a rotational movement of the further conveying means 2′ is in each case coupled to the rotational movement of one of the conveying means 2 on the same side of the conveying path. This is brought about here by providing toothed-wheel means between the conveying means 2 and the further conveying means 2′. The toothed-wheel means comprise toothed wheels 20 which are rigidly and concentrically connected to the axes of rotation of the conveying means 2 and the further conveying means 2′. The toothed wheels 20 are coupled to one another via an intermediate toothed wheel 21. This means that a toothed wheel 20 of the conveying means 2 is in engagement with a corresponding intermediate toothed wheel 21 and imparts a rotational movement to the latter. The intermediate toothed wheel 21 is, in turn, in engagement with a toothed wheel 20 of the corresponding further conveying means 2′ and thereby imparts to the further conveying means 2′ a rotational movement which is in the same direction as the rotational movement of the conveying means 2. Since in each case only conveying means 2 and further conveying means 2′ which are arranged on the same side of the conveying path are coupled to one another, the vertical displaceability of the conveying means 2 on the upper side of the conveying path is thereby not impaired. It is understood that the further conveying means 2′ on the upper side of the conveying path are likewise vertically displaceably mounted. The intermediate toothed wheels 21 are necessary in this example to ensure that the conveying means 2 and the further conveying means 2′ rotate in the same direction.

The rotating speed of the conveying means 2′ is not the same as that of the conveying means 2 owing to the different diameter. The different rotating speed of the conveying means 2′ is set by the transmission ratio of the toothed wheels 20. The peripheral speed of the periphery, rolling on the stock to be conveyed 1, of the conveying means 2 and 2′ is thereby the same despite the different diameters.

As a departure form the above-described examples, various modifications are possible. In particular, it is possible to combine features of the various examples with one another. Thus, roll-shaped conveying means, for example, can be combined with conveying means based on the conveying discs. Furthermore, it would be possible to design the further conveying means as roll-shaped conveying means. Also, it is not absolutely necessary to provide the conveying means on both sides of the conveying path. The described conveying device with drive means which are based on a spindle part and a mating wheel with cams can be advantageously employed even with a single conveying means 2 which is movably mounted.

### LIST OF REFERENCE SYMBOLS

| | |
|---|---|
| 1 | Stock to be conveyed |
| 2, 2′ | Conveying means |
| 3 | Drive shaft |
| 4 | Spindle part |
| 5 | Mating wheel |
| 6 | Cam |
| 7 | Spacer |
| 8 | Projection of the thread-like structure |
| 9 | Groove of the thread-like structure |
| 10 | Conveying discs |
| 11 | Offset conveying discs |
| 12 | Conveying direction |
| 13 | Container substructure |
| 14 | Side walls |
| 15 | Bottom |
| 16 | Removable cover |
| 17 | Treatment zone |
| 18 | Bevel wheel |
| 19 | Mating bevel wheel |
| 20 | Toothed wheel |
| 21 | Intermediate toothed wheel |

1-21. (canceled)

22. A conveying device, comprising
rotatably mounted conveying means for moving in a conveying direction stock to be conveyed, and
drive means which impart a rotational movement to the conveying means, so that the stock to be conveyed is moved by the rotational movement in the conveying direction,
the conveying means being arranged, with respect to a conveying path of the stock to be conveyed, in such a way that they come into contact with the stock to be conveyed when the latter passes through the conveying path, and
an axis of rotation of the conveying means extending in a lateral direction perpendicular to the conveying direction,
wherein at least one spindle part, which is shaped like a cylinder and has a thread-like structure on an outer surface, and at least one rotation means, with projections arranged along its periphery and extending in the direction of an axis of rotation of the rotation means, are provided, at least one of the projections being in engagement with the thread-like structure of the spindle part, so that a rotational movement of the spindle part is converted into a rotational movement of the rotation means, the rotational movement of the rotation means being coupled to the rotational movement of the conveying means.

23. A conveying device according to claim 22, wherein the conveying means are arranged on both sides of the conveying path, the conveying means on at least one side of the conveying path being mounted in a manner movable in the vertical direction, a first rotation means, the rotational movement of which is coupled to the rotational movement of conveying means arranged on a first side of the conveying path, comprising projections which are arranged along its periphery and extend in the direction of its axis of rotation and of which at least one is in engagement with the thread-like structure of the at least one spindle part, and a second rotation means, the rotational movement of which is coupled to the rotational movement of conveying means arranged on a second side, opposite the first side, of the conveying path, comprising projections which are arranged along its periphery and extend in the direction of its axis of rotation and of which at least one is in engagement with the thread-like structure of the at least one spindle part.

24. A conveying device according to claim 22, wherein the at least one spindle part is arranged on a drive shaft running parallel to the conveying direction, so that it rotates together with the drive shaft.

25. A conveying device according to claim 24, wherein the conveying device comprises a plurality of conveying means which are arranged at positions along the conveying direction, there being provided for each position a spindle part which is arranged at a corresponding position of the drive shaft.

26. A conveying device according to claim 22, wherein the rotation means and the conveying means, the rotational movements of which are coupled to one another, are mounted in a manner rotating with one another on a common axis.

27. A conveying device according to claim 23, wherein an axis of rotation of the at least one spindle part is situated in the vertical direction between the axis of rotation of the first rotation means of the conveying means on the first side of the conveying path and the axis of rotation of the second rotation means of the conveying means on the second side of the conveying path.

28. A conveying device according to claim 27, wherein the conveying means are movably mounted at least on one side of the conveying path, and wherein the axis of rotation of the at least one spindle part is arranged in a manner offset, by a proportion of a maximum displacement of the movably mounted conveying means in the vertical direction, in this direction.

29. A conveying device according to claim 22, wherein the conveying device comprises, arranged parallel to the conveying means in each case on the same side of the conveying path, further rotatably mounted conveying means, the axis of rotation of which is arranged parallel to the axis of rotation of the conveying means, the conveying device being designed in such a way that the rotational movement of the conveying means imparts a rotational movement with the same direction of rotation to the further conveying means.

30. A conveying device according to claim 29, wherein the conveying device comprises toothed-wheel means which convert the rotational movement of the conveying means into the rotational movement of the further conveying means.

31. A conveying device according to claim 29, wherein the further conveying means are designed as roll-shaped conveying means extending in the lateral direction.

32. A conveying device according to claim 29, wherein the further conveying means comprise conveying discs which are arranged in a manner spaced apart on a common axis.

33. A conveying device according to claim 22, wherein the conveying means are designed as roll-shaped conveying means extending in the lateral direction.

34. A conveying device according to claim 22, wherein the conveying means comprise conveying discs which are arranged in a manner spaced apart on a common axis.

35. A conveying device according to claim 25, wherein conveying discs adjacent in the conveying direction are arranged in a manner offset in the lateral direction.

36. A conveying device according to claim 35, wherein the conveying discs are arranged in a manner spaced apart in the conveying direction such that conveying discs arranged adjacently in the conveying direction overlap in the conveying direction.

37. A conveying device according to claim 22, wherein a pitch of the thread-like structure, the extent of the at least one spindle part along its axis of rotation and the radial spacing of the projections of the at least one rotation means from the axis of rotation of the rotation means are designed in such a way that, for a given rotating speed of the at least one spindle part, a desired conveying speed of the conveying means results.

38. A conveying device according to claim 22, wherein the conveying device comprises a plurality of the conveying means, and wherein the conveying device is designed in such a way that, for each of the conveying means, the same conveying speed results.

39. A conveying device according to claim 22, wherein the conveying means are mounted in a manner movable in a vertical direction perpendicular to the conveying direction, in order to be able to adapt to variations in the thickness of the stock to be conveyed, in the vertical direction.

40. A conveying device according to claim 22, wherein the conveying device is designed for conveying plate- or foil-like stock to be conveyed.

41. A conveying device according to claim 22, wherein the conveying device is designed for use in a wet-chemical or electrolytic treatment plant.

42. A treatment plant for the wet-chemical or electrolytic treatment of a workpiece comprising a conveying device according to claim 1.
